(19) United States
(12) Patent Application Publication
(10) Pub. No.: US 2012/0280755 A1
(43) Pub. Date: Nov. 8, 2012

(54) FLIP-CHIP POWER AMPLIFIER AND IMPEDANCE MATCHING NETWORK

(75) Inventor: Peter V. Wright, Portland, OR (US)

(73) Assignee: TRIQUINT SEMICONDUCTOR, INC., Hillsboro, OR (US)

(21) Appl. No.: 13/100,743

(22) Filed: May 4, 2011

(51) Int. Cl. H03F 3/14; H01L 21/50

(52) U.S. Cl. 330/307; 438/108; 257/E21.499

(57) ABSTRACT

Embodiments of circuits, apparatuses, and systems for a flip-chip power amplifier and impedance matching network are disclosed. Other embodiments may be described and claimed.

### FIELD

Embodiments of the present disclosure relate generally to the field of circuits, and more particularly to a flip-chip power amplifier and impedance matching network.

### BACKGROUND

Impedance matching networks with large transformation ratios are required on an output of a power amplifier given practical supply voltages and antenna impedances. These transformation ratios typically exceed 12:1. Such an impedance matching network is implemented by a combination of surface mounted devices (SMDs), e.g., capacitors, and conductive elements, e.g., inductors, in a laminate carrier. The SMDs on the laminate carrier and the conductive elements in the laminate carrier have significant variability in production and occupy a significant portion of the power amplifier's footprint.

### BRIEF DESCRIPTION OF THE DRAWINGS

Embodiments are illustrated by way of example and not by way of limitation in the figures of the accompanying drawings, in which like references indicate similar elements and in which:

FIG. 1 illustrates a cross-sectional view of a radio frequency power amplifier module in accordance with some embodiments.

FIG. 2 illustrates a top view of a radio frequency power amplifier module in accordance with some embodiments.

FIG. 3 illustrates a top view of a radio frequency power amplifier module in accordance with some embodiments.

FIG. 4 is a circuit diagram of radio frequency power amplifier module in accordance with some embodiments.

FIG. 5 is a flowchart depicting a process of assembling a radio frequency power amplifier module in accordance with some embodiments.

FIG. 6 is an exemplary wireless communication device in accordance with some embodiments of the present disclosure.

### DETAILED DESCRIPTION

Various aspects of the illustrative embodiments will be described using terms commonly employed by those skilled in the art to convey the substance of their work to others skilled in the art. However, it will be apparent to those skilled in the art that alternate embodiments may be practiced with only some of the described aspects. For purposes of explanation, specific devices and configurations are set forth in order to provide a thorough understanding of the illustrative embodiments. However, it will be apparent to one skilled in the art that alternate embodiments may be practiced without the specific details. In other instances, well-known features are omitted or simplified in order not to obscure the illustrative embodiments.

Further, various operations will be described as multiple discrete operations, in turn, in a manner that is most helpful in understanding the present disclosure; however, the order of description should not be construed as to imply that these operations are necessarily order dependent. In particular, these operations need not be performed in the order of presentation.

The phrase “in one embodiment” is used repeatedly. The phrase generally does not refer to the same embodiment; however, it may. The terms “comprising,” “having,” and “including” are synonymous, unless the context dictates otherwise.

In providing some clarifying context to language that may be used in connection with various embodiments, the phrases “A/B” and “A and/or B” mean (A), (B), or (A and B); and the phrase “A, B, and/or C” means (A), (B), (C), (A and B), (A and C), (B and C) or (A, B and C).

The term “coupled with,” along with its derivatives, may be used herein. “Coupled” may mean one or more of the following. “Coupled” may mean that two or more elements are in direct physical or electrical contact. However, “coupled” may also mean that two or more elements indirectly contact each other, but yet still cooperate or interact with each other, and may mean that one or more other elements are coupled or connected between the elements that are said to be coupled to each other.

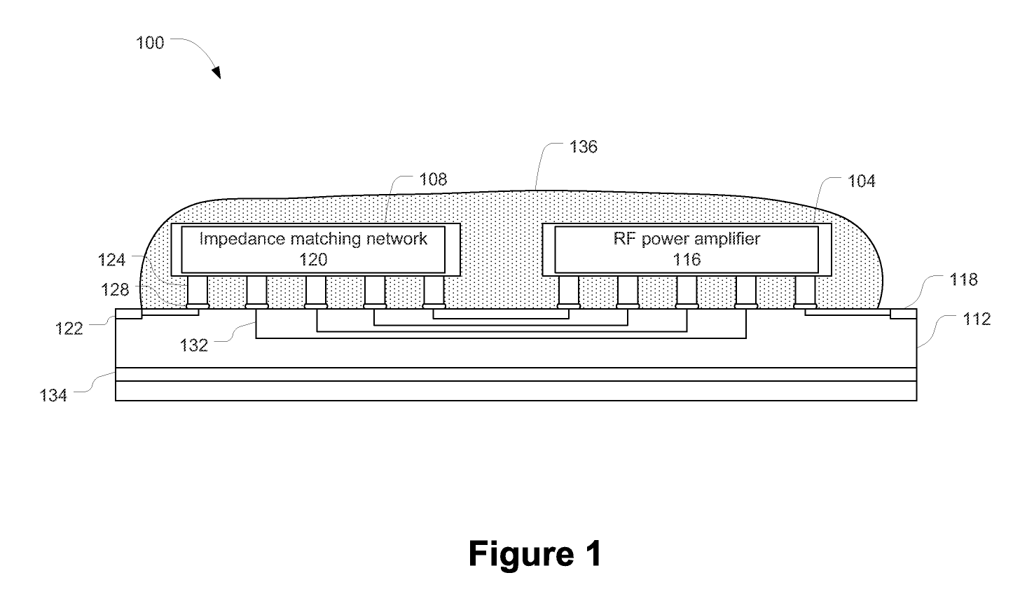

FIG. 1 illustrates a cross-sectional view of a radio frequency (RF) power amplifier (PA) module 100 in accordance with various embodiments. The RF PA module 100 includes an active die 104 and a passive die 108 coupled with a carrier substrate 112. An active die, as used herein, may refer to a die that includes one or more integrated active components. An active component is a component capable of providing some power gain, such as a transistor. The active components of the active die 104 may form an RF power amplifier 116 that is designed to amplify an RF signal received at an input 118 of the RF PA module 100. The active die 104 may be realized on, for example, a silicon or gallium arsenide (GaAs) substrate.

A passive die, as used herein, may refer to a die that strictly includes integrated passive components. A passive component is a reactive component that is not capable of providing a power gain, such as inductors, capacitors, resistors, and/or transmission-line components. The passive components of the passive die 108 may form an impedance matching network 120 that implements at least a majority of impedance matching between the RF power amplifier 116 and an output 122 of the RF PA module 100. In some embodiments, one or more of the passive components of the impedance matching network 120 may be disposed in the carrier substrate 112, with the remaining passive components disposed in the passive die 108. The passive die 108 may be realized on, for example, a low-loss substrate such as high-resistivity silicon, glass, or mechanical GaAs substrate.

Both the active die 104 and the passive die 108 may be flip-chip coupled with the carrier substrate 112 through an array of metal posts 124 and solder caps 128. In some embodiments, the metal posts 124 may be copper posts and the solder caps 128 may be tin and/or silver caps. The metal posts 124 and solder caps 128 may mechanically and electrically couple the active die 104 and passive die 108 with the carrier substrate 112. The carrier substrate 112 may include traces 132 that electrically couple the RF power amplifier 116 with the impedance matching network 120. The traces 132 may also electrically couple the RF power amplifier 116 with the input 118; and the impedance matching network 120 with the output 122. The carrier substrate 112 may be a laminate carrier, e.g., a printed circuit board (PCB). In some embodiments, the carrier substrate 112 may be one or more lead frames that are attached to another, larger substrate (e.g., a PCB).

All of the metal posts 124 may have an equal height of at least approximately 50 micrometers (μm), for example. Such a height may provide a desired electrical isolation between the dies, e.g., active die 104 and passive die 108, and the carrier substrate 112. Without realizing this desired electrical isolation, the electrical fields of the circuits in the dies may be adversely affected by a ground plane 134 in the carrier substrate 112.

A height of at least approximately 50 pm may also facilitate flow of an epoxy and filler particles 136 around and between the metal posts 124. The epoxy and filler particles 136 may be injected into a mold so that it covers and protects the dies from moisture and/or mechanical stress. If the metal posts 124 are less than approximately 50 μm, flow of the epoxy and filler particles 136 may be restricted between the dies and the carrier substrate 112 due to sizes of the particles within the epoxy and filler particles 136.

Implementing the impedance matching network 120 in the passive die 108 and flip-chip coupling both the passive die 108 and the active die 104 to the carrier substrate 112 may provide a number of advantages. One such advantage is the realization of relatively low parasitic resistances in an electrical path from the RF power amplifier 116 to the impedance matching network 120 through the carrier substrate 112, as compared to a prior art RF PA module.

A prior art RF PA module may have an active die coupled with an off-die impedance matching network through wire bonds. The wire bonds coupling the active die to the off-die impedance matching network will have variable loop lengths that add parasitic resistance to the electrical paths therebetween and increase manufacturing variability. Due to the low impedance at an output of an RF power amplifier, e.g., 2 ohms, excessive parasitic resistance in the electrical paths is associated with a significant performance cost.

The flip-chip coupling of the dies in the present disclosure, on the other hand, may be done with very high die-placement accuracy. This high die-placement accuracy, along with the low resistance and inductance of the metal posts 124, may result in the low parasitic resistance of the electrical paths between the RF power amplifier 116 and the impedance matching network 120. This, in turn, facilitates implementation of the impedance matching network 120 in the passive die 108, even with the relatively low output impedance of the RF power amplifier 116 of the active die 104. Manufacturing yields are also improved by the reduced variability in the assembly process.

Implementing both inductors and capacitors of the impedance matching network 120 in the passive die 108, rather than relying on SMDs, may also decrease the need for interconnect paths and mounting pads. This may reduce routing loss and overall footprint of the RF PA module 100.

Furthermore, the RF PA module 100, by avoiding the incorporation of critical magnetic or transmission line structures in the carrier substrate 112, avoids the significant variability in production and large critical dimensions associated with batch processes. Instead, the integrated passive components of the impedance matching network 120 may be reliably constructed using photolithographically-controlled processes.

Integrating passive components in the passive die 108 may also provide a significant cost advantage compared to providing passive components in either the active die 104, the carrier substrate 112, or as SMDs attached to the surface of the carrier substrate 112.

Integrating passive components in the passive die 108 may still further provide a performance advantage due to component variations that track each other on the passive die 108 (e.g., capacitance of all capacitors move in the same direction). This leads to higher yields than if one component is at the high end of its tolerance range and another component is at the low end, which frequently occurs with SMDs.

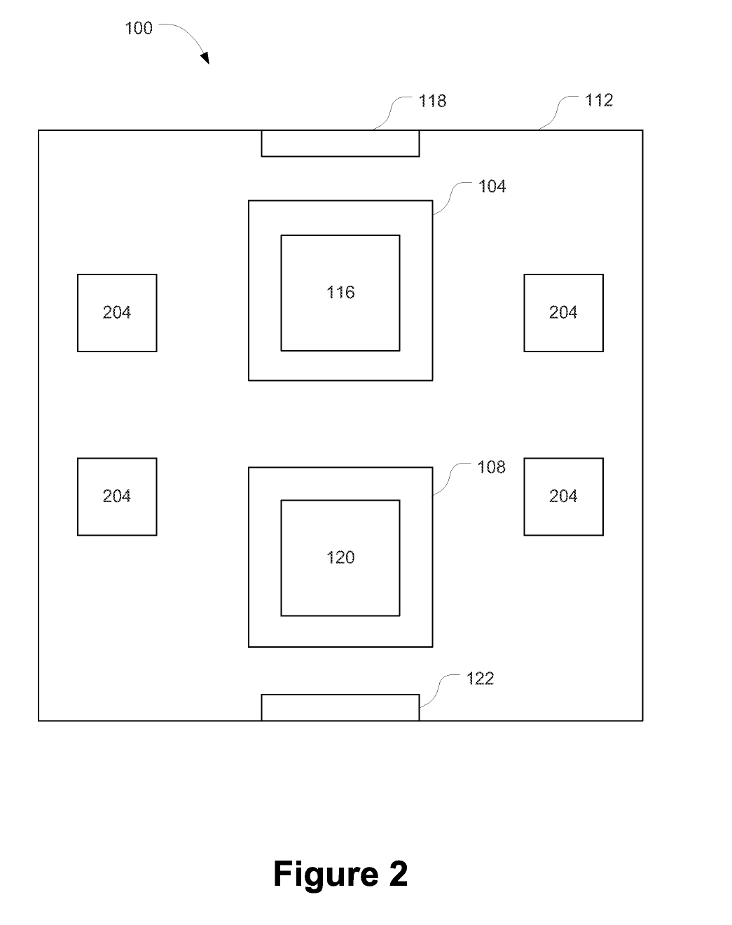

FIG. 2 is a top view of the RF PA module 100 in accordance with some embodiments. The RF PA module 100 is shown in FIG. 2 without the epoxy and filler particles 136. In addition to the active die 104 and the passive die 108 the RF PA module 100 may include a number of bypass capacitors 204. The bypass capacitors 204 may be set across power lines and may operate to reduce noise that may be present in a power delivery system.

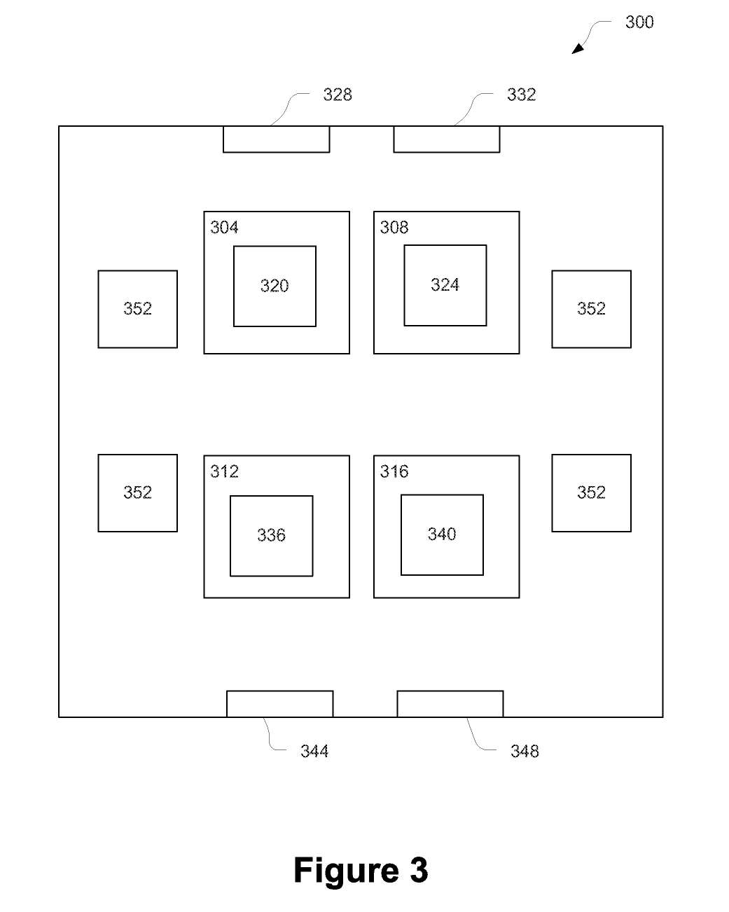

While the RF PA module 100 is shown with one RF power amplifier, i.e., RF power amplifier 116, coupled with one impedance matching network, i.e., impedance matching network 120, other embodiments may have other numbers of RF power amplifiers and/or impedance matching networks included in an RF PA module. FIG. 3 illustrates one such example.

FIG. 3 is a top view of an RF PA module 300 in accordance with some embodiments. The RF PA module 300 may be similar to RF PA module 100, with like-named components being substantially interchangeable. However, the RF PA module 300 may include two active dies, e.g., active die 304 and active die 308, and two passive dies, e.g., passive die 312 and passive die 316. The RF PA module 300 may be a dual-band RF PA module having a first RF power amplifier 320, implemented in active die 304, for operation in a first band of frequencies, e.g., a relatively high band of frequencies. The RF PA module 300 may also include a second RF power amplifier 324, implemented in active die 308, for operation in a second band of frequencies, e.g., a relatively low band of frequencies. The first RF power amplifier 320 may be electrically coupled with a first input 328, while the second RF power amplifier 324 may be electrically coupled with a second input 332.

The first RF power amplifier 320 may also be electrically coupled with a first impedance matching network 336 implemented in the passive die 312. Similarly, the second RF power amplifier 324 may also be electrically coupled with a second impedance matching network 340 implemented in the passive die 316. The first impedance matching network 336 may also be electrically coupled with a first output 344 and the second impedance matching network 340 may also be electrically coupled with a second output 348.

The RF PA module 300 may also include one or more bypass capacitors 352, similar to RF PA module 100.

While FIG. 3 shows that each impedance matching network is implemented in its own passive die other embodiments may include more than one impedance matching network implemented in one passive die. Similarly, while FIG. 3 shows that each RF power amplifier is implemented in its own active die, other embodiments may include more than one RF power amplifier implemented in one active die.

In some embodiments, the architecture of the impedance matching network may be selected in a manner to facilitate implementation through use of integrated passive components on a passive die. For example, a lattice matching network may provide a compact architecture that is particularly suitable for implementation on a passive die.

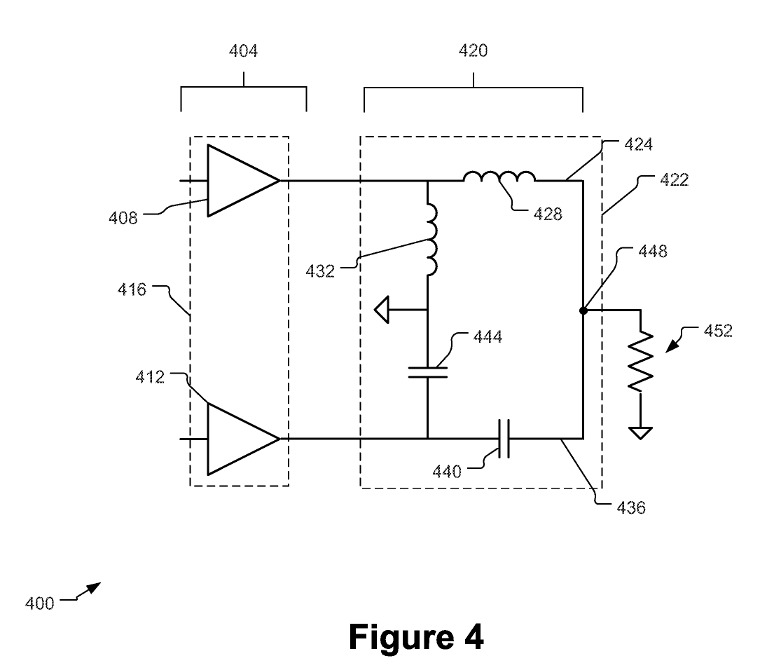

FIG. 4 is a circuit diagram of an RF PA module 400 in accordance with various embodiments. The RF PA module 400 may be similar to, and substantially interchangeable with, RF PA module 100 and/or RF PA module 300. The RF PA module 400 includes a quadrature RF power amplifier 404 having a first PA 408 and a second PA 412 operating in quadrature, i.e., with a 90 degree phase delta. The first PA 408 and the second PA 412 may be implemented in an active die 416.

The RF PA module 400 may also include a quadrature lattice matching network 420 electrically coupled with the quadrature RF power amplifier 404. The quadrature lattice matching network 420 may be implemented in a passive die 422 and may provide quadrature phase combining and impedance matching in a three-port reactive network. The quadrature lattice matching network 420 may include a first path 424, having a series inductor 428 and a shunt inductor 432, and a second path 436 having a series capacitor 440 and a shunt capacitor 444. The outputs of the two parallel paths 424 and 436 may be combined to a single-ended output at the output node 448 as illustrated. Resistor 452 may represent an output load. The compact architecture of the quadrature lattice matching network 420 may be amenable to full implementation on the passive die 422 while still providing a number of desirable impedance matching characteristics such as load-insensitivity, low insertion loss, low cost, and reduced voltage standing wave ratio (VSWR) on the output node 448.

While FIG. 4 shows an architecture of a lattice matching network that may be particularly effective in an embodiment of this disclosure, i.e., quadrature lattice matching network 420, other embodiments may use other lattice matching networks, such as any of those shown and described in U.S. patent application Ser. No. 13/070,424, titled “QUADRATURE LATTICE MATCHING NETWORK,” filed Mar. 23, 2011, which is hereby incorporated by reference in its entirety. In other embodiments, impedance matching networks other than lattice matching networks may be employed.

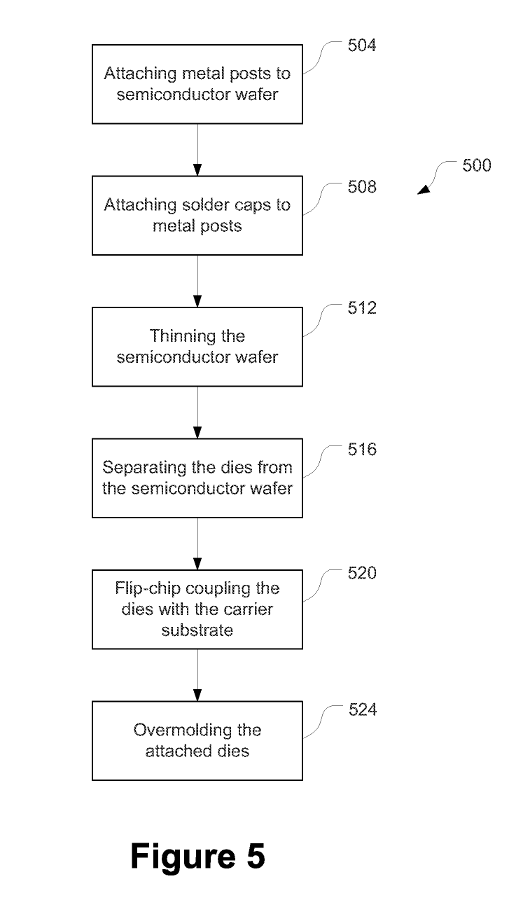

FIG. 5 is a flowchart 500 depicting a process of assembling an RF PA module in accordance with various embodiments. In block 504, “Attaching metal posts to the semiconductor wafer,” the assembly process may involve attaching metal posts to the semiconductor wafer.

Attachment of one component to another component, as used herein, could be achieved by any of a number of possible microfabrication processes. A particular microfabrication process may be selected in light of the materials to be attached and other process variables. Such microfabrication processes may involve techniques such as, but not limited to, deposition (or growth), patterning, and etching.

At block 508, “Attaching solder caps to metal posts,” the assembly process may involve attaching a solder cap to each of the metal posts.

At block 512, “Thinning the semiconductor wafer,” the assembly process may involve reducing the thickness of the semiconductor wafer. Prior to block 512, it may be desirable for the semiconductor wafer to have a certain thickness to increase mechanical stability and avoid warping during high temperature process steps. In some embodiments, the thickness of the silicon wafer may be approximately 750 μm for these process steps. However, the dimensions of the final package may be substantially smaller and the thickness of the semiconductor wafer may, therefore, be reduced at block 512. In some embodiments, the thickness of the semiconductor wafer may be reduced to less than 250 μm.

At block 516, “Separating the dies from the semiconductor wafer,” the assembly process may involve separation of the dies, which may include active and/or passive dies, from the semiconductor wafer. In some embodiments, the semiconductor wafer may be mounted on a dicing tape that has a sticky backing to hold the dies in place once separated. The separating of the dies may be performed by scribing and breaking, dicing with a dicing saw, or cutting with a laser.

At block 520, “Flip-chip coupling the dies with carrier substrate,” the assembly process may involve flip-chip coupling of the dies, i.e., an active and a passive die, with the carrier substrate. The dies, with metal posts and solder caps attached, may be placed in the appropriate position on the substrate carrier. Placement of the dies may be tightly controlled with very high accuracy. As discussed above, the accurate placement of the dies may contribute to increased performance of the RF PA module as compared to the prior art RF PA modules that rely on wire bonding and/or SMDs.

Once the dies are placed, the carrier substrate and the dies may be heated to a temperature that is at least a reflow temperature associated with the solder caps and less than a reflow temperature associated with the metal posts. The solder caps will then reflow to mechanically and electrically couple the dies with the carrier substrate.

At block 524, “Overmolding the attached dies,” one or more molds may be placed over the dies and epoxy and filler particles may be inserted into the mold(s). The epoxy may cure and the mold(s) may be removed. As discussed above, the cured epoxy may serve to protect the dies on the carrier substrate from moisture and mechanical stress.

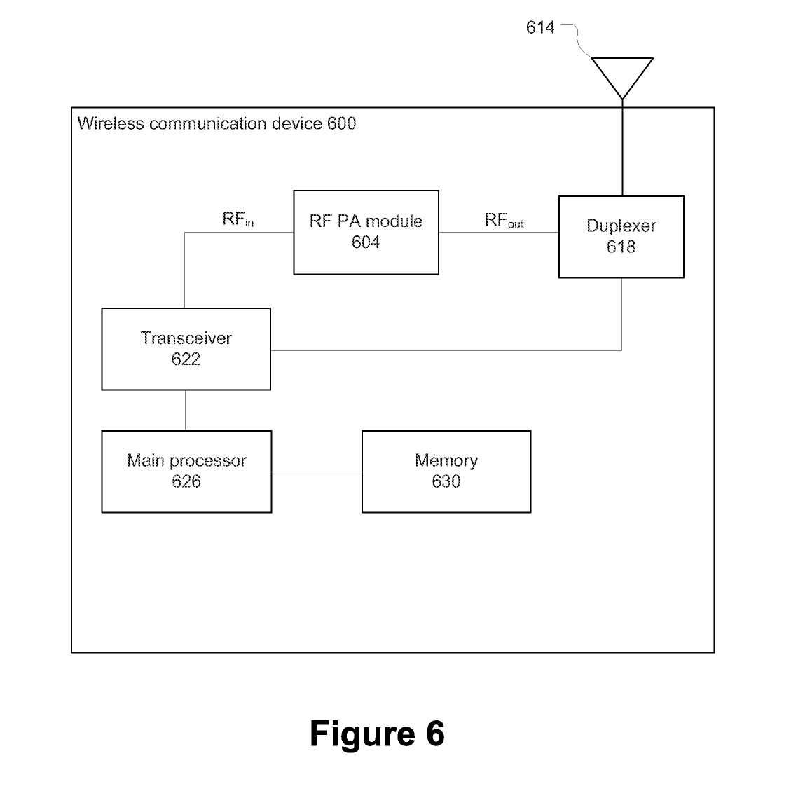

A block diagram of an exemplary wireless communication device 600 incorporating an RF PA module 604, which may be similar to RF PA modules 100, 300, and/or 400, is illustrated in FIG. 6 in accordance with some embodiments. In addition to the RF PA module 604, the wireless communication device 600 may have an antenna structure 614, a duplexer 618, a transceiver 622, a main processor 626, and a memory 630 coupled with each other at least as shown. While the wireless communication device 600 is shown with transmitting and receiving capabilities, other embodiments may include devices with only transmitting or only receiving capabilities.

In various embodiments, the wireless communication device 600 may be, but is not limited to, a mobile telephone, a paging device, a personal digital assistant, a text-messaging device, a portable computer, a desktop computer, a base station, a subscriber station, an access point, a radar, a satellite communication device, or any other device capable of wirelessly transmitting/receiving RF signals.

The main processor 626 may execute a basic operating system program, stored in the memory 630, in order to control the overall operation of the wireless communication device 600. For example, the main processor 626 may control the reception of signals and the transmission of signals by transceiver 622. The main processor 626 may be capable of executing other processes and programs resident in the memory 630 and may move data into or out of memory 630, as desired by an executing process.

The transceiver 622 may receive outgoing data (e.g., voice data, web data, e-mail, signaling data, etc.) from the main processor 626, may generate the RFᵢₙ signal(s) to represent the outgoing data, and provide the RFᵢₙ signal(s) to the RF PA module 604. The transceiver 622 may also control the RF PA module 604 to operate in selected bands and in either full-power or backoff-power modes.

The RF PA module 604 may amplify the RFᵢₙ signal(s) to provide RFₒᵤₜ signal(s) as described herein. The RFₒᵤₜ signal(s) may be forwarded to the duplexer 618 and then to the antenna structure 614 for an over-the-air (OTA) transmission.

In a similar manner, the transceiver 622 may receive an incoming OTA signal from the antenna structure 614 through the duplexer 618. The transceiver 622 may process and send the incoming signal to the main processor 626 for further processing.

In various embodiments, the antenna structure 614 may include one or more directional and/or omnidirectional antennas, including, e.g., a dipole antenna, a monopole antenna, a patch antenna, a loop antenna, a microstrip antenna or any other type of antenna suitable for OTA transmission/reception of RF signals.

Those skilled in the art will recognize that the wireless communication device 600 is given by way of example and that, for simplicity and clarity, only so much of the construction and operation of the wireless communication device 600 as is necessary for an understanding of the embodiments is shown and described. Various embodiments contemplate any suitable component or combination of components performing any suitable tasks in association with wireless communication device 600, according to particular needs. Moreover, it is understood that the wireless communication device 600 should not be construed to limit the types of devices in which embodiments may be implemented.

Although the present disclosure has been described in terms of the above-illustrated embodiments, it will be appreciated by those of ordinary skill in the art that a wide variety of alternate and/or equivalent implementations calculated to achieve the same purposes may be substituted for the specific embodiments shown and described without departing from the scope of the present disclosure. Those with skill in the art will readily appreciate that the teachings of the present disclosure may be implemented in a wide variety of embodiments. This description is intended to be regarded as illustrative instead of restrictive.

What is claimed is:

1. An apparatus comprising:
a carrier substrate;
a first die having a plurality of integrated active devices that form a radio frequency (RF) power amplifier, wherein the first die is flip-chip coupled with the carrier substrate through a first plurality of metal posts;
a second die having a plurality of integrated passive devices that form an impedance matching network that is electrically coupled with the RF power amplifier through the carrier substrate, wherein the second die is flip-chip coupled with the carrier substrate through a second plurality of metal posts.

2. The apparatus of claim 1, wherein the first and second plurality of metal posts have an equal height.

3. The apparatus of claim 2, wherein the equal height is approximately 50 micrometers or greater.

4. The apparatus of claim 3, wherein the first and second plurality of metal posts comprise copper posts.

5. The apparatus of claim 1, wherein the first and second plurality of metal posts comprise copper posts.

6. The apparatus of claim 1, wherein the first die is flip-chip coupled with the carrier substrate through a first plurality of solder caps coupled to respective ones of the first plurality of metal posts, and the second die is flip-chip coupled with the carrier substrate through a second plurality of solder caps respectively coupled with the second plurality of metal posts.

7. The apparatus of claim 1, wherein the carrier substrate is a laminate carrier substrate.

8. The apparatus of claim 1, wherein the carrier substrate is one or more lead frames.

9. The apparatus of claim 1, wherein the second die does not contain any active devices.

10. The apparatus of claim 1, wherein the plurality of integrated passive devices comprise an inductor and a capacitor.

11. The apparatus of claim 1, wherein the impedance matching network further comprises one or more passive devices in the carrier substrate.

12. The apparatus of claim 1, wherein the impedance matching network comprises a lattice matching network.

13. The apparatus of claim 1, wherein the RF power amplifier is a quadrature power amplifier, and the impedance matching network is a quadrature lattice matching network.

14. The apparatus of claim 1, wherein the RF power amplifier is a first RF power amplifier configured to operate in a first band of frequencies, the impedance matching network is a first impedance matching network, and the apparatus further comprises:
a third die having a second RF power amplifier configured to operate in a second band of frequencies, wherein the third die is flip-chip coupled with the carrier substrate through a third plurality of metal posts; and
a second impedance matching network electrically coupled with the second RF power amplifier through the carrier substrate.

15. The apparatus of claim 14, wherein the second impedance matching network is disposed in the second die or in a fourth die that is flip-chip coupled with the carrier substrate.

16. A method comprising:
attaching a first array of metal posts to an active die, having a plurality of integrated active devices that form a radio frequency (RF) power amplifier;
attaching a second array of metal posts to a passive die, having a plurality of integrated passive devices that form an impedance matching network;
attaching solder caps to individual metal posts of the first and second arrays of metal posts; and
flip-chip coupling the first and second die with a carrier substrate to electrically couple the RF power amplifier with the impedance matching network.

17. The method of claim 16, further comprising:
placing one or more molds over the first and second die; and
inserting an epoxy and filler particles into the one or more molds.

18. The method of claim 16, wherein the first and second array of metal posts have an equal height that is approximately 50 micrometers or greater.

19. The method of claim 16, wherein the first and second array of metal posts comprise copper posts.

20. A system comprising:
a transceiver configured to generate a radio frequency (RF) signal;
a radio frequency (RF) power amplifier module, coupled with the transceiver, and configured to amplify the RF signal to provide an amplified RF signal, wherein the RF power amplifier module includes:
a carrier substrate;
an active die having a radio frequency (RF) power amplifier, wherein the active die is flip-chip coupled with the carrier substrate through a first plurality of metal posts;
a passive die having an impedance matching network that is electrically coupled with the RF power amplifier through the carrier substrate, wherein the passive die is flip-chip coupled with the carrier substrate through a second plurality of metal posts; and
an antenna to transmit the amplified RF signal over the air.

21. The system of claim 20, wherein the first and second plurality of metal posts comprise copper posts.
